(19) United States
(12) Patent Application Publication
(10) Pub. No.: US 2018/0228036 A1
(43) Pub. Date: Aug. 9, 2018

(54) FLEXIBLE DISPLAY DEVICE

(71) Applicant: Microjet Technology Co., Ltd., Hsinchu (TW)

(72) Inventors: Hao-Jan MOU, Hsinchu (TW); Ta-Wei HSUEH, Hsinchu (TW); Shih-Chang CHEN, Hsinchu (TW); Jia-Yu LIAO, Hsinchu (TW); Yung-Lung HAN, Hsinchu (TW); Chi-Feng HUANG, Hsinchu (TW); Wei-Ming LEE, Hsinchu (TW)

(73) Assignee: Microjet Technology Co., Ltd., Hsinchu (TW)

(21) Appl. No.: 15/884,782

(22) Filed: Jan. 31, 2018

(30) Foreign Application Priority Data
Feb. 8, 2017 (TW) 106104174

(51) Int. Cl. H05K 5/00; H05K 5/02

(52) U.S. Cl. CPC H05K 5/0017; H05K 5/0217

(57) ABSTRACT

A flexible display device comprises a main body, a gas transportation device, and a flexible module comprising a flexible panel and a soft cushion. The flexible panel comprises a flexible substrate having a first surface and a second surface, and a display assembly. The display assembly is disposed on the first surface. The soft cushion is adhered on the second surface. The gas transportation device is disposed in the main body. The gas transportation device has a gas inlet and a gas outlet communicated with the soft cushion. The flexible module is received by a receiving space. When the flexible panel and the soft cushion are unfolded outwardly, gas is inputted from the gas inlet and transmitted to the soft cushion through the gas outlet, so that the soft cushion is inflated, and the flexible panel is stably supported by the soft cushion and not easy to be deformed.

### CROSS-REFERENCE TO RELATED APPLICATION

This application claims priority from Taiwan Patent Application No. 106104174, filed on Feb. 8, 2017, the entire contents of which are incorporated herein by reference for all purposes.

### FIELD OF THE INVENTION

The present invention relates to a flexible display device, and more particularly to a flexible display device having soft cushion that is inflatable for support.

### BACKGROUND OF THE INVENTION

Accompanying with the improvement of technology, the conventional planar video and audio display device cannot satisfy the demands of general users. For the convenience of carrying and using, a bendable, foldable, and rollable flexible display device and related technologies are strongly developed. However, the largest challenge faced by the flexible display device is how to be properly bended, folded and stored when not being used, and how to be set as an even and level plane when being used. In the present technology of prior art, for unfolding and folding the flexible display device, a support structure such as a guiding rail or several stacked rods, or a chain support member is usually utilized. However, any of above-mentioned mechanical means are required to provide certain strength for supporting the periphery of the flexible display device by which the flexible display device is capable of being even and level in the unfolded status. Under this circumstance, those support structures become inextricable and heavy, and occupy large space, which are disadvantages in developing a potable and miniature flexible display device.

Therefore, there is actually an urgent need to develop a flexible display device, which can be quickly unfolded, maintained even and level and not easily deformed in the unfolded status, in miniature size for being portable, and can be wound for easy storage.

### SUMMARY OF THE INVENTION

The main purpose of the present invention is to provide a flexible display device which can be applied to each kind of bendable, foldable and rollable flexible display equipment. The flexible display device has a soft cushion disposed below the flexible panel. When the flexible display device is in an unfolded status, the soft cushion is inflated by a gas transportation device so as to stably supporting the flexible panel, thus the flexible panel is maintained flat and even, and is not easy to deform during use. Such design is also beneficial to keep the flexible display device in compact size and light in weight.

In accordance with an aspect of the present invention, there is provided a flexible display device. The flexible display device comprises a flexible module, a main body and a gas transportation device. The flexible module is convertible between an unfolded status and a folded status. The flexible module comprises a flexible panel and a soft cushion. The flexible panel comprises a flexible substrate and a display assembly. The flexible substrate has a first surface and an opposing second surface, while the display assembly is disposed on the first surface, and the soft cushion is attached on the second surface of the flexible substrate. The main body has a receiving space inside where the gas transportation device is disposed. The gas transportation device has a gas inlet and a gas outlet, wherein the gas outlet is communicated with the soft cushion. The flexible module is received by the receiving space when it is in the folded status. When the flexible module is in the unfolded status, the flexible panel and the soft cushion of the flexible module are unfolded outwardly, and gas is inputted from the gas inlet and transmitted to the soft cushion through the gas outlet, which is driven by the gas transportation device. Hence, the soft cushion is inflated with the gas, and the flexible panel is supported by the inflated soft cushion.

In accordance with another aspect of the present invention, there is provided a flexible display device. The flexible display device comprises a flexible panel. The flexible panel comprises a flexible substrate, a display assembly, a soft cushion and a gas transportation device. The flexible substrate has a first surface and an opposing second surface, while the display assembly is disposed on the first surface, and the soft cushion is attached on the second surface of the flexible substrate. The gas transportation device has a gas inlet and a gas outlet. The gas outlet is communicated with the soft cushion for transmitting gas to inflate the soft cushion.

The above contents of the present invention will become more readily apparent to those ordinarily skilled in the art after reviewing the following detailed description and accompanying drawings, in which:

### BRIEF DESCRIPTION OF THE DRAWINGS

FIG. 1A schematically illustrates a perspective view of the exterior of a flexible display device according to an embodiment of the present invention;

FIG. 1B schematically illustrates a sectional view of the flexible display device of FIG. 1A;

FIG. 2A schematically illustrates a sectional view of the flexible panel and the soft cushion of the flexible module of FIG. 1A, in which the flexible module is in the folded status;

FIG. 2B schematically illustrates a top view of the flexible panel and the soft cushion of the flexible module of FIG. 1A, in which the flexible module is in the folded status;

FIG. 3 schematically illustrates the control system of the flexible display device of FIG. 1A;

FIG. 4A schematically illustrates the flexible panel and the soft cushion of the flexible module of FIG. 1A, in which the flexible module is in an initial unfolded status ; and

FIG. 4B schematically illustrates the flexible module shown in FIG. 4A after the soft cushion thereof has been inflated.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

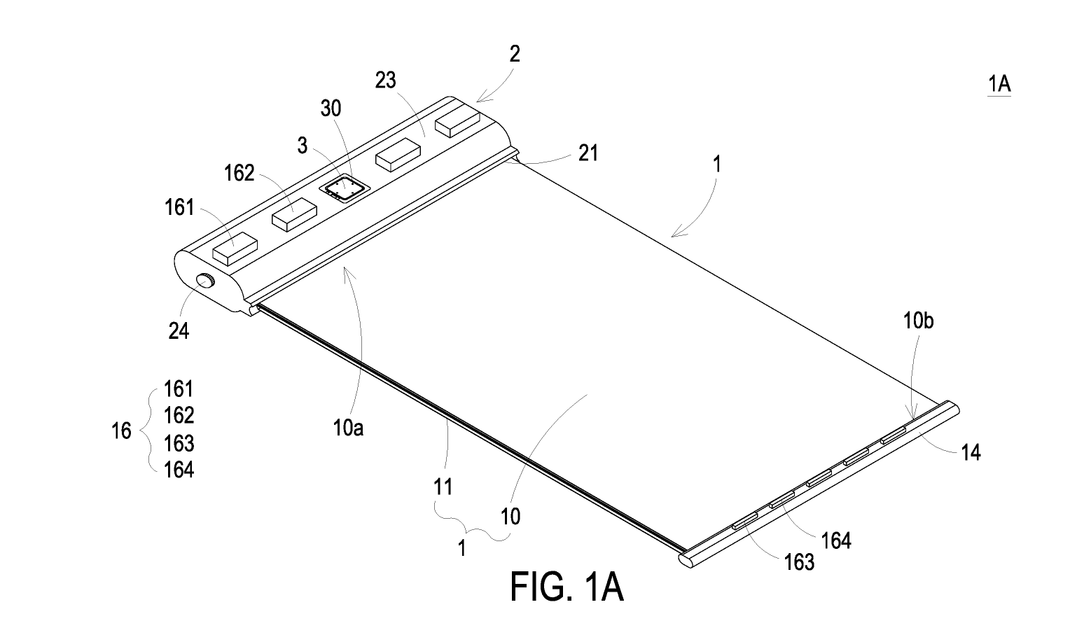

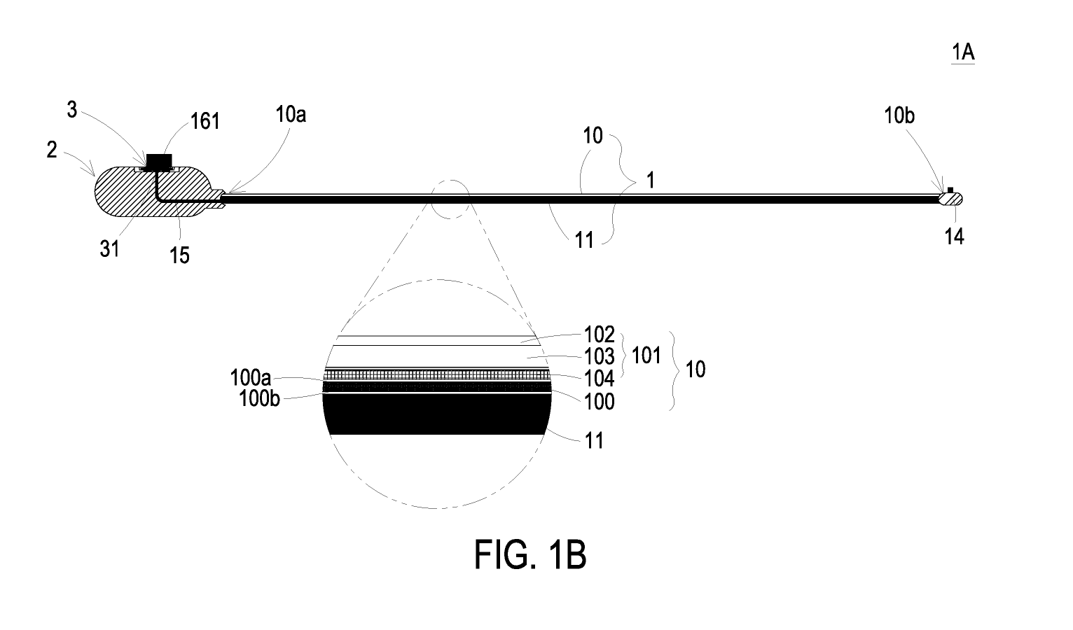

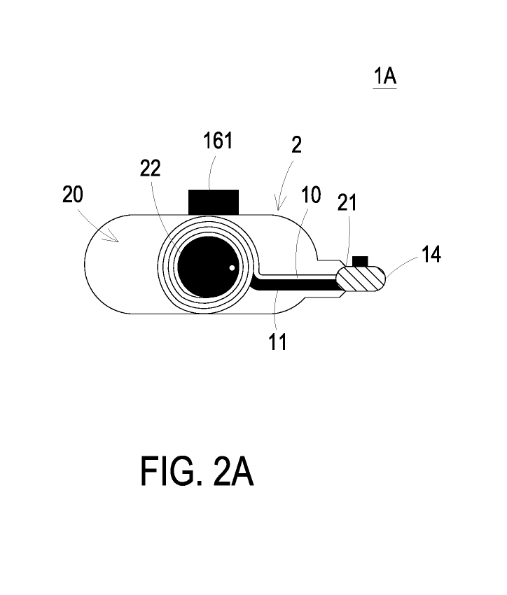

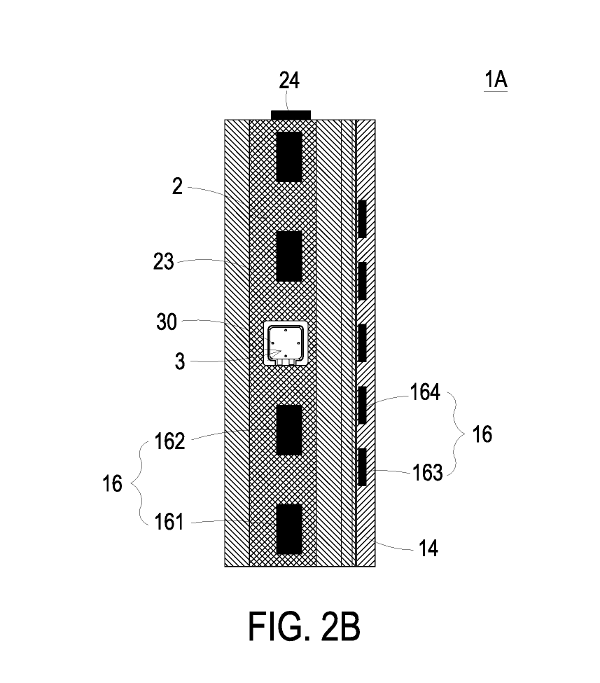

Please refer to FIG. 1A and FIG. 1B. FIG. 1A schematically illustrates a perspective view of the exterior of a flexible display device according to an embodiment of the present invention. FIG. 1B schematically illustrates a sectional view of the flexible display device of FIG. 1A. The flexible display device of the present invention can be applied to each kind of bendable, foldable and rollable flexible display equipment. As shown in FIG. 1A, the flexible display device 1A comprises a flexible module 1, a main body 2 and a gas transportation device 3. The flexible module 1 is composed of a flexible panel 10 and a soft cushion 11, and is convertible between an unfolded status and a folded status. The flexible panel 10 is a panel that is flexible, bendable and rollable, and as shown in FIG. 1B, the flexible panel 10 includes a flexible substrate 100 and a display assembly 101. The flexible substrate 100 has a first surface 100a and an opposing second surface 100b. The display assembly 101 is disposed on the first surface 100a, and the soft cushion 11 is attached on the second surface 100b of the flexible substrate 100 and parallel thereto. The gas transportation device 3 is disposed in the main body 2, having a gas inlet 30 and a gas outlet 31, wherein the gas outlet 31 is communicated with the soft cushion 11. The main body 2 has a receiving space 20 inside (see FIG. 2A) for storing the flexible module 1 in the folded status. When the flexible module 1 is turning from the folded status to the unfolded status, being unfolded outwardly from the main body 2, the gas transportation device 3 is in action to guide a gas into the gas inlet 30 thereof and out from the gas outlet 31 thereof to be transported to inflate the soft cushion 11, so that the flexible module 1 is supported by the inflated soft cushion 11 below.

Please refer to FIG. 1A, FIG. 1B and FIG. 2A. FIG. 2A schematically illustrates a sectional view of the flexible panel and the soft cushion of the flexible module of FIG. 1A, in which the flexible module is in the folded status. As shown in FIG. 1A, FIG. 1B and FIG. 2A, the main body 2 of the flexible display device 1A has an elongated box structure, but not limited herein. The main body 2 has the receiving space 20 inside and an opening 21 at a lateral edge thereof, wherein the receiving space 20 and the opening 21 are in communication with each other. There is a surface 23 on top of the main body 2. In this embodiment, the gas transportation device 3 is embedded in the surface 23 of the main body 2. However, the way of disposing the gas transportation device 3 is not limited thereto, since the gas transportation device 3 may also be disposed inside the main body 2 to meet the practical demands. The gas transportation device 3 is in communication with outside through the gas inlet 30. That is, the gas can be inputted to the gas transportation device 3 from the gas inlet 30. Meanwhile, as shown in FIG. 1B, the gas outlet 31 of the gas transportation device 3 is communicated with the soft cushion 11 through an airflow passage 15. The airflow passage 15 may be formed by connecting a plurality of tiny hollowed hoses, and is to provide access for the gas.

In this embodiment, the soft cushion 11 is an integrally formed inflatable structure, and a connection surface of the soft cushion 11 has a plurality of soft cushion holes (not shown). The airflow passage 15 comprises a plurality of airflow passage holes (not shown), wherein the amount, size and position of the airflow passage holes of the airflow passage 15 are corresponding to those of the soft cushion holes of the soft cushion 11. The airflow passage holes and the soft cushion holes are correspondingly in connection, by which the airflow passage 15 and the soft cushion 11 are in communication that gas can pass therethrough.

Please refer to 1B. The flexible panel 10 comprises the flexible substrate 100 and the display assembly 101. The flexible substrate 100 has two opposite surfaces, i.e. the first surface 100a and the second surface 100b. The display assembly 101 is correspondingly disposed on the first surface 100a. In this embodiment, the display assembly 101 comprises a cover layer 102, a display layer 103 and a sensor layer 104, wherein the sensor layer 104 is disposed on the flexible substrate 100, the display layer 103 is disposed on the sensor layer 104, and the cover layer 102 correspondingly covers the sensor layer 104.

In this embodiment, the flexible substrate 100 is made of a flexible soft substrate, which is not only bendable but also has supporting capacity to support the display module 101 disposed thereon. The topmost cover layer 102 is made of transparent thin plastic or transparent thin glass for protecting the display layer 103 and the sensor layer 104, and can be omitted in some other embodiments. The display layer 103 may be a plasma display plate, a liquid crystal display plate, or an organic light-emitting diode plate, but not limited thereto. The sensor layer 104 may be a capacitor layer, which is for sensing external pressures and correspondingly generating feedback signals in response thereto. Through disposing the flexible display assembly 101 on the first surface 100a of the flexible substrate 100, which includes the cover layer 102, the display layer 103 and the sensor layer 104 as mentioned above, as well as disposing the soft cushion 11 on the second surface 100b of the flexible substrate 100, the flexible panel 10 is in a flexible, bendable and soft status and has stable support, and the flexible panel 10 and the soft cushion 11 are flexible and rollable, so that they can be folded and stored in the receiving space 20 of the main body 2.

As shown in FIG. 2A and FIG. 2B, the flexible display device 1A further comprises a pivot 22 and a knob 24. The knob 24 is disposed on a lateral side of the main body 2 to be fixed on an end of the pivot 22, while the pivot 22 is disposed in the receiving space 20. Moreover, a first lateral side portion 10a (see FIG. 1A) of the flexible module 1 is fixed to the pivot 22 laterally, so that the first lateral side portion 10a can be wound around the pivot 22 to be rolled up and stored in the receiving space 20. In this embodiment, a second lateral side portion 10b of the flexible module 1, which is opposing to the first lateral side portion 10a, has an abutting member 14. The abutting member 14 may be an elongated rod, the length of which is substantially equal to the length of the second lateral side portion 10b, but not limited herein. When the flexible module 1 is rolled up and stored in the receiving space 20, the abutting member 14 is abutting against an opening 21 of the receiving space 20 and abutting a lateral side of the main body 2, as shown in FIG. 2B.

In this embodiment, as shown in FIG. 1A and FIG. 2B, the flexible display device 1A further comprises a plurality of buttons 16, including but not limited to a start switch 161, a winding switch 162 or 163, and a pressure relief switch 164 . . . etc. The buttons 16 may be disposed on the surface 23 of the main body 2 or on the abutting member 14. The amount, the corresponding function, the disposing position of the buttons 16 can be varied to meet the practical demands, but not limited thereto.

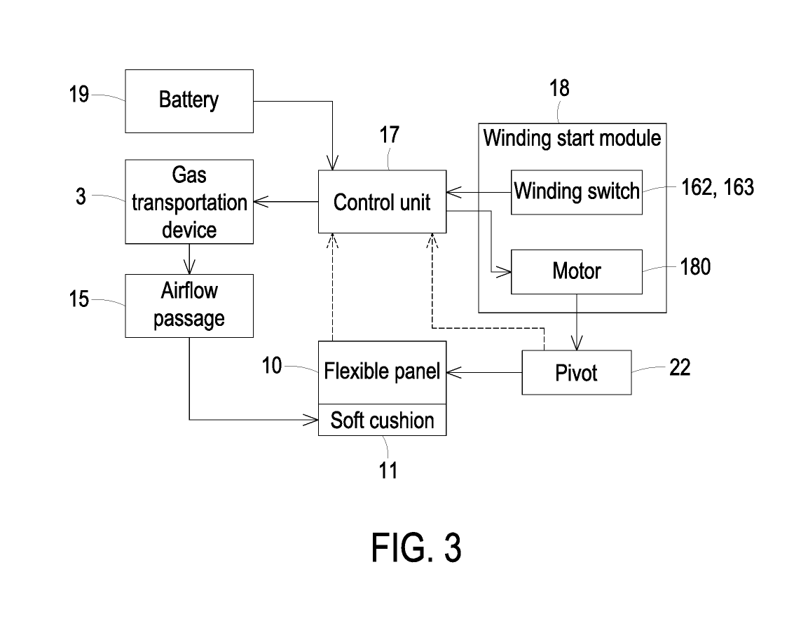

Please refer to FIG. 3. FIG. 3 schematically illustrates the control system of the flexible display device of FIG. 1A. In this embodiment, the control system of the flexible display device 1A is shown as FIG. 3. The flexible display device 1A has a control unit 17. The control unit 17 is disposed in the receiving space 20 of the main body 2, but not limited herein. The control unit 17 is electrically connected with a winding start module 18, the gas transportation device 3 and a battery 19. In this embodiment, the winding start module 18 comprises two winding switches 162 and 163, and a motor 180. For example, the winding switch 162 can be the enable button (ON) that controls the flexible panel 10 and the soft cushion 11 of the flexible module 1 to be unfolded outwardly so as to be in the unfolded status, while another winding switch 163 can be the disable button (OFF) that controls the flexible panel 10 and the soft cushion 11 to be folded and wound back in the receiving space 20 so as to be in the folded status. In some other embodiments, the winding switch 162 and the winding switch 163 can be combined to be one single button, triggering different signals in manner of switching different sections or pressing for multiple times. The operating way and the disposition positions of the at least one winding switch of the winding start module 18 are varied to meet the practical demands and not described in details hereinafter. The battery 19 may be a lithium battery or a mercury battery disposed in the receiving space 20 of the main body 2, but not limited herein, and is used for providing electric power to the control unit 17.

In this embodiment, when the winding switch 163 (OFF) which controls the winding of the flexible panel 10 and the soft cushion 11 of the flexible module 1 is triggered, a pressure relief signal and a winding signal are sent to the control unit 17 in sequence. After receiving the pressure relief signal, the control unit 17 enables the gas transportation device 3 to operate, by which the pressure of the soft cushion 11 is released through the airflow passage 15 and the soft cushion 11 is evacuated to be in a vacuum state. At this moment, although there is no gas supporting in the soft cushion 11, the flexible panel 10 is still supported by the soft cushion 11 to be even and level, because the soft cushion 11 is in a negative pressure state. Afterwards, according to the winding signal which is received later, the control unit 17 enables the motor 180 to operate. Since the motor 180 is connected to the pivot 22 in this embodiment, the pivot 22 is driven by the motor 180 to rotate in a direction (e.g. in the clockwise direction), thereby rolling the flexible panel 10 and the soft cushion 11 up to the receiving space 20 of the main body 2.

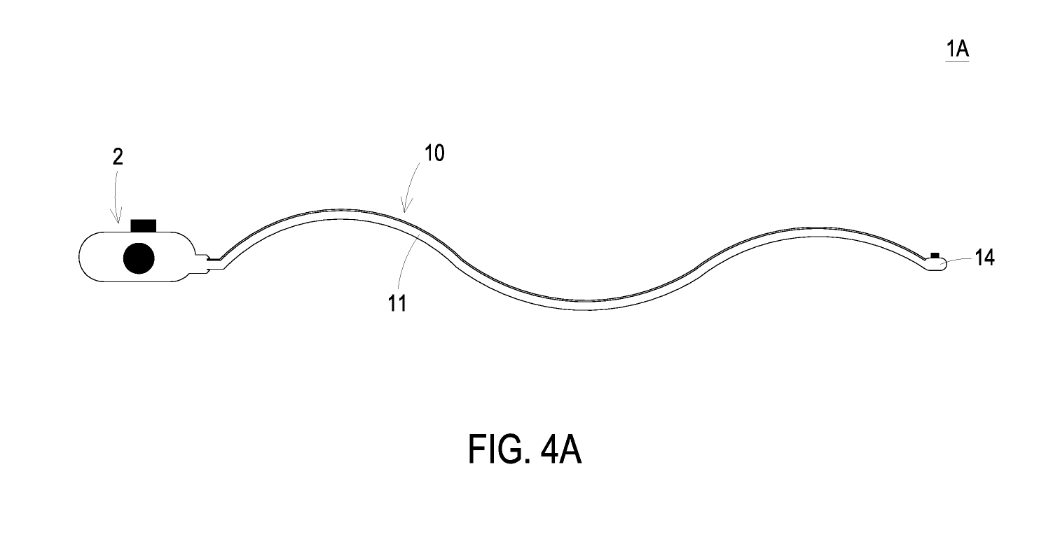

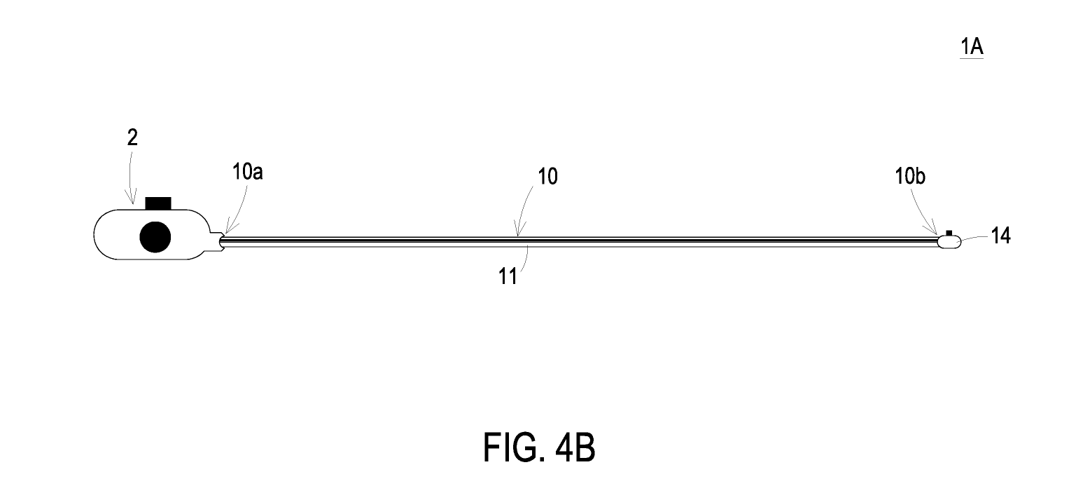

Please refer to FIG. 1A, FIG. 1B, FIG. 3, FIG. 4A and FIG. 4B. FIG. 4A schematically illustrates the flexible panel and the soft cushion of the flexible module of FIG. 1A, in which the flexible module is in an initial unfolded status. FIG. 4B schematically illustrates the flexible module shown in FIG. 4A after the soft cushion thereof has been inflated. In this embodiment, the flexible display device 1A is unfolded in an automatic manner. The flexible panel 10 and the soft cushion 11 of the flexible module 1 are automatically unfolded from the receiving space 20 of the main body 2, but not limited herein, because the flexible panel 10 and the soft cushion 11 of the flexible module 1 can also be manually unfolded outwardly. In former case, when the user presses the winding switch 162 (ON) which controls the unfolding of the flexible panel 10 and the soft cushion 11, the winding switch 162 sends an unfolding signal to the control unit 17. After receiving the unfolding signal, the control unit 17 accordingly enables the motor 180 to operate, by which the pivot 22 is driven to rotate in an opposite direction (e.g. in the counter-clockwise direction), thereby unfolding the flexible panel 10 and the soft cushion 11 of the flexible module 1, which stretch out from the receiving space 20 through the opening 21. Due to flexibility of the flexible panel 10, the flexible module 1 is not completely even and flat when being initially unfolded, as shown in FIG. 4A.

Please refer to FIG. 4B. After the flexible panel 10 and the soft cushion 11 have been entirely unfolded, the operation of unfolding is stopped, by means of a latch mechanism which may disposed on the first lateral side portion 10a of the flexible module 1 or disposed on the pivot 22. Meanwhile, an inflating signal is sent to the control module 17. The control unit 17 accordingly enables the gas transportation device 3 to rapidly transmit the gas, from the gas outlet 31 into the soft cushion 11 through the airflow passage 15, to inflate and expand the soft cushion 11. The inflated soft cushion 11 is capable of supporting the flexible panel 10 to maintain flat and even, thus the flexible display device 1A being ready to use by pressing the start switch 161 to activate the flexible panel 10.

In some other embodiments, the flexible panel 10 and the soft cushion 11 of the flexible module 1 can be manually unfolded by the user. The only thing that the user needs to do is to hold the abutting member 14, which is disposed on the second lateral side portion 10b of the flexible module 1, and pull it outwardly. As described above, after the flexible panel 10 and the soft cushion 11 have been entirely unfolded, they can no longer be pulled, due to the latch mechanism disposed on the first lateral side portion 10a of the flexible module 1 or disposed on the pivot 22. Meanwhile, the inflating signal is sent to the control module 17, and the soft cushion 11 is inflated by the gas transportation device 3 driven by the control module 17, so that the flexible panel 10 is supported by the inflated soft cushion 11 to maintain flat and even and ready to use.

Through the inflating action by the gas transportation device 3, the gas is guided into the soft cushion 11 through the airflow passage 15, and the inflated and expanded soft cushion 11 provides the flexible panel 10, which is attached on the soft cushion 11, with stable support, so that the flexible panel 10 can stay even and level. Such design can also be applied to each kind of display panel.

The foregoing embodiment shows a flexible display device which can be folded and stored in a main body. However, in some other embodiments, the flexible display device may be a device without the man body. Through the flexible panel and the soft cushion of the flexible module attaching with each other and the soft cushion can be inflated by the gas transportation device to support the flexible panel to stay even and flat, a flexible display device which is bendable, stackable, foldable or rollable can also be achieved. Therefore, the application of the flexible display device of the present invention may be changed according to the actual conditions and is not limited to the foregoing implementation examples.

From the above description, the present invention provides a flexible display device applied to each kind of bendable, foldable and rollable flexible display equipment. By disposing the soft cushion beneath the flexible panel in which the soft cushion is inflated or exhausted by the gas transportation device, the flexible panel is stably supported by the inflated soft cushion when being in the unfolded status. Hence, the flexible panel is maintained flat and even, and is not easily deformed during use. Meanwhile, the total size of the flexible display device is kept in compact.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A flexible display device, comprising:
a flexible module convertible between an unfolded status and a folded status, comprising:
a flexible panel, comprising:
a flexible substrate having a first surface and an opposing second surface; and
a display assembly disposed on the first surface of the flexible substrate; and
a soft cushion attached on the second surface of the flexible substrate;
a main body having a receiving space inside; and
a gas transportation device disposed in the main body and having a gas inlet and a gas outlet, wherein the gas outlet is communicated with the soft cushion,
wherein the flexible module in the folded status is received by the receiving space, and when the flexible module is in the unfolded status and the flexible panel and the soft cushion of the flexible module are unfolded outwardly, the gas transportation device operates so that gas is inputted from the gas inlet and transmitted to the soft cushion through the gas outlet to inflate the soft cushion, and the flexible panel is supported by the inflated soft cushion.

2. The flexible display device according to claim 1, wherein the display assembly comprises a sensor layer disposed on the first surface of the flexible substrate, and a display layer disposed on the sensor layer.

3. The flexible display device according to claim 2, wherein the display assembly further comprises a cover layer disposed on the display layer.

4. The flexible display device according to claim 1, wherein a pivot is disposed in the receiving space and a first lateral side portion of the flexible module is fixed on the pivot, so that the flexible module in the folded status is wound around the pivot and received in the receiving space.

5. The flexible display device according to claim 4, wherein an abutting member is mounted on a second lateral side portion of the flexible module, and when the flexible module is wound and received in the receiving space, the abutting member is abutted against an opening of the receiving space.

6. The flexible display device according to claim 5, wherein the flexible panel and the soft cushion of the flexible module are unfolded outwardly by manually pulling the second lateral side portion of the flexible module outwardly to make the flexible module in the unfolded status.

7. The flexible display device according to claim 5, wherein a knob is disposed on a lateral side of the main body, and the knob is connected to an end of the pivot.

8. The flexible display device according to claim 4 further comprising a winding start module, the winding start module comprising at least one winding switch and a motor, wherein the winding switch is connected with a control unit, when the winding switch is triggered, the control unit receives a winding signal and accordingly controls the motor to drive the rotation of the pivot connected to the motor, so that the flexible panel and the soft cushion of the flexible module are correspondingly wound and received in the receiving space in which the flexible module is in the folded status.

9. The flexible display device according to claim 8, wherein when the winding switch is triggered, the control unit receives an unfolding signal and accordingly control the motor to drive the rotation of the pivot connected to the motor, and the flexible panel and the soft cushion of the flexible module are unfolded outwardly from the receiving space in which the flexible module is in the unfolded status.

10. The flexible display device according to claim 8 further comprising a battery for providing electric power to the control unit.

11. The flexible display device according to claim 1, wherein the gas transportation device is embedded on a surface of the main body, and the gas transportation device is communicated with the soft cushion through an airflow passage.

12. A flexible display device, comprising:
a flexible panel, comprising:
a flexible substrate having a first surface and an opposing second surface;
a display assembly disposed on the first surface of the flexible substrate;
a soft cushion attached on the second surface of the flexible substrate; and
a gas transportation device having a gas inlet and a gas outlet, and the gas outlet is communicated with the soft cushion for transporting gas to inflate the soft cushion.

13. The flexible display device according to claim 12, wherein the display assembly comprises a sensor layer and a display layer, the sensor layer is disposed on the first surface of the flexible substrate, and the display layer is disposed on the sensor layer.

14. The flexible display device according to claim 13, wherein the display assembly further comprises a cover layer disposed on the display layer.
